(19) United States
(12) Patent Application Publication
(10) Pub. No.: US 2002/0058368 A1
(43) Pub. Date: May 16, 2002

(54) Method of fabricating a dummy gate electrode of an ESD protecting device

(76) Inventor: Horng-Huei Tseng, Hsinchu (TW)

Correspondence Address: INTELLECTUAL PROPERTY SOLUTIONS, PLLC, 1300 PENNSYLVANIA AVE, N.W., WASHINGTON, DC, 20004, US

(21) Appl. No.: 09/790,800

(22) Filed: Feb. 23, 2001

(30) Foreign Application Priority Data
Nov. 14, 2000 (TW) 89124085

(51) Int. Cl. H01L 21/338; H01L 21/336; H01L 21/44

(52) U.S. Cl. 438/183; 438/281; 438/601

(57) ABSTRACT

A method of fabricating a semiconductor device has the steps of: forming a sacrificial layer having a first trench for exposing a first predetermined area of the substrate on the ESD protecting device region; forming a first impurity layer of a second conductivity type in the first predetermined area of the substrate on the ESD protecting region; patterning the sacrificial layer to form a second trench for exposing a second predetermined area of the substrate on the internal circuit device region and a third trench for exposing a third predetermined area of the substrate on the ESD protecting device region; forming a gate insulating layer on the exposed substrate, and then filling the first trench, the second trench and the third trench with a conductive layer which serves as a dummy gate electrode of the ESD protecting device, a gate electrode of the internal circuit device and a gate electrode of the ESD protecting device respectively; removing the sacrificial layer and then forming a second impurity layer of the second conductivity type in the exposed substrate at both sides of the gate electrodes and the dummy electrode respectively; and forming a silicide layer on the gate electrodes, the dummy gate electrode and the second impurity layer.

### BACKGROUND OF THE INVENTION

1. Field of the Invention

The present invention relates in general to a method of fabricating a semiconductor device. In particular, the present invention relates to a method of fabricating a semiconductor device by using a self-aligned silicide process.

2. Description of the Related Art

A self-aligned silicide (salicide) source/drain process is widely applied to most of the currently used integrated circuit devices to increase the operation speed of a circuit. That is, the overall resistance of a semiconductor device can be reduced by forming silicide that has low resistance on source/drain regions, thus accordingly achieving high-speed operation of the semiconductor device.

However, an electrostatic discharge (ESD) failure voltage of an ESD protecting device fabricated by the salicide source/drain process is considerably lower than an ESD failure voltage of a semiconductor device fabricated by a general non-silicide source/drain process, which results in deterioration of a product. That is, the salicide source/drain process has a reverse effect on the ESD protecting characteristics. Accordingly, to solve such a problem, there is provided a method of fabricating a semiconductor device wherein a silicide blocking portion is formed with respect to the whole ESD protecting device when forming a salicide layer on the source/drain regions, so that the silicide may not be formed on the ESD device. However, since a protecting film is needed for the silicide blocking portion, the additional provided deposition, heat treatment and photo-etching processes would cause the electrical characteristics of the internal circuit device to deteriorate.

U.S. Pat. No. 6,110,771 discloses a method of fabricating a dummy gate on the ESD protecting device to solve the problem of ESD failure voltage in salicide source/drain process. With reference to FIGS. 1A through 1D, the method of fabricating a dummy gate on the ESD protecting device is described. First, as shown in FIG. 1A, a p-type semiconductor substrate 12 includes an internal circuit device region A and an ESD protecting device region B, and a plurality of isolation regions 14 formed on the p-type semiconductor substrate 12 by a well-known device isolating process such as a local oxidation of silicon (LOCOS) process or a shallow trench process. Here, the other region except for the isolation regions 14 in the semiconductor substrate 12 is an active area. A photoresist layer 16 is patterned over the substrate 12 and has a trench 15 that exposes a first predetermined area of the substrate 12 on the ESD protecting device region B. Next, using the photoresist layer 16 as a mask, n-type impurity ions are implanted into the exposed substrate 12 to form a first impurity layer 18.

As shown in FIG. 1B, after the photoresist layer 16 is stripped off, a gate oxide film 20 and a polysilicon layer 22 are sequentially deposited and then patterned, thereby forming a gate electrode 22a of the internal circuit device at the region A and a gate electrode 22b of the ESD protecting device at the region B, respectively. At the same time, a dummy gate electrode 22c is formed over the first impurity layer 20, being separated from the gate electrode 22b of the ESD protecting device. The dummy gate electrode 22c which serves as a silicide blocking portion prevents silicide from being formed on the drain of the ESD protecting device at region B in a following silicide forming process. Next, by using the gate electrodes 22a, 22b and the dummy gate electrode 22c as masks, a second impurity layer 24 is formed by implanting n-type impurity ions into the exposed substrate 12. The second impurity layer 24 is generally called a lightly doped drain (LDD).

As shown in FIG. 1C, by depositing silicon nitride and performing the anisotropic etching process, sidewall spacers 26 are formed at side surfaces of the gate electrodes 22a, 22b and the dummy gate electrode 22c, respectively. Then, a third impurity layer 28 is formed by implanting n-type impurity ions into the exposed substrate 12 by using the sidewall spacers 26, the gate electrodes 22a, 22b and the dummy gate electrode 22c as masks. The third impurity layer 28, which has shallower depth and lower density than the second impurity layer 24, serves as source/drain electrodes of the gate electrode 22a of the internal circuit device and gate electrode 22b of the ESD protecting device together with the first impurity layer 18 and the second impurity layer 24. Besides, the third impurity layer 28b serves as a drain electrode of the dummy gate 22c, and the third impurity layer 28c serves as a part of the drain electrode of the ESD protecting device to form a source/drain-wire contact portion that is connected to various devices in the substrate 12.

As shown in FIG. 1D, a metal layer, such as Ti, Co, Pt, Ni, Pd, Cr, Mo, Ta, W, is formed on the resultant surface of the substrate 12 and then a heat treatment is performed to have a silicified reaction between the silicon and the metal layer, thereby forming a silicide layer 30, and then a portion of the metal layer where the silicified reaction does not occur is selectively removed. As a result, the silicide layers 30 are formed on the gate electrodes 22a, 22b, the dummy gate electrode 22c and third impurity layer 28, respectively.

However, as far as a novel semiconductor process with much high integration is concerned, a shift distance d would be found between the first impurity layer 18 and the dummy gate electrode 22c, as shown in FIG. 1B′, since the impurity layer 18 is patterned by the photoresist layer 16 and the dummy gate electrode 22c is patterned by another mask. Therefore, according the above-mentioned method, the dummy gate electrode 22c would not be accurately sited in the middle region over the first impurity layer 18 and even be shifted away from the first impurity layer 18. This will reduce the performance of the dummy gate 22c. Also, this will lead to misalignment of the second impurity layer 20, the third impurity layer 28 and the silicide layer 30, thereby decreasing the performance of the internal circuit device and the ESD protecting device.

### SUMMARY OF THE INVENTION

An object of the present invention is to provide a method of fabricating a dummy gate on of an ESD protecting device to solve a problem of the shift distance between the dummy gate and the first impurity layer.

The method of fabricating a semiconductor device, comprises the steps of: forming a sacrificial layer having a first trench for exposing a first predetermined area of the substrate on the ESD protecting device region; forming a first impurity layer of a second conductivity type in the first predetermined area of the substrate on the ESD protecting region; patterning the sacrificial layer to form a second trench for exposing a second predetermined area of the substrate on the internal circuit device region and a third trench for exposing a third predetermined area of the substrate on the ESD protecting device region; forming a gate insulating layer on the exposed substrate, and then filling the first trench, the second trench and the third trench with a conductive layer which serves as a dummy gate electrode of the ESD protecting device, a gate electrode of the internal circuit device and a gate electrode of the ESD protecting device respectively; removing the sacrificial layer and then forming a second impurity layer of the second conductivity type in the exposed substrate at both sides of the gate electrodes and the dummy electrode respectively; and forming a silicide layer on the gate electrodes, the dummy gate electrode and the second impurity layer.

It is an advantage of the present invention that the first impurity layer is defined by patterning the sacrificial layer, and the dummy gate electrode is also defined by patterning the sacrificial layer in the follow-up process. Consequently, this can ensure that the dummy gate electrode is disposed in the middle region of the first impurity layer. Without the shift distance between the dummy gate electrode and the first impurity layer, the performance of the dummy gate electrode and the semiconductor device are both increased.

This and other objectives of the present invention will no doubt become obvious to those of ordinary skill in the art after having read the following detailed description of the preferred embodiment which is illustrated in the various figures and drawings.

### BRIEF DESCRIPTION OF THE DRAWINGS

The present invention can be more fully understood by reading the subsequent detailed description in conjunction with the examples and references made to the accompanying drawings, wherein:

FIGS. 1A through 1D show a method of fabricating a dummy gate on the ESD protecting device.

FIGS. 2A to 2I show a method of forming a dummy gate of an ESD protecting device according to the first embodiment of the present invention.

FIGS. 3A to 3F show a method of fabricating the dummy gate electrode of the ESD protecting device according to the second embodiment of the present invention.

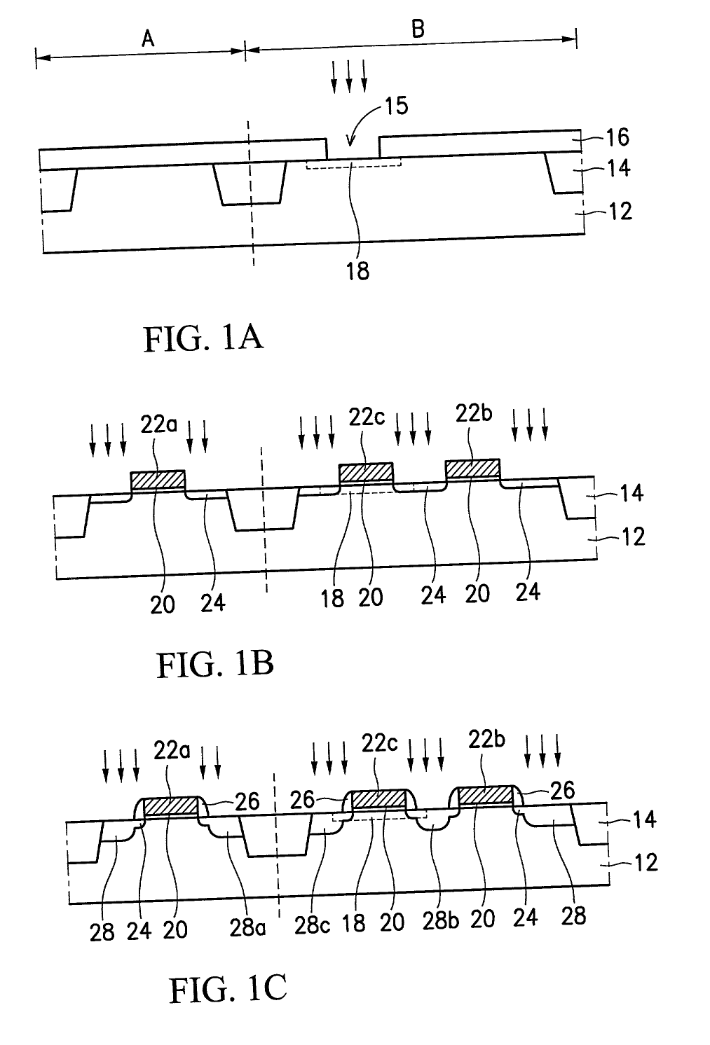

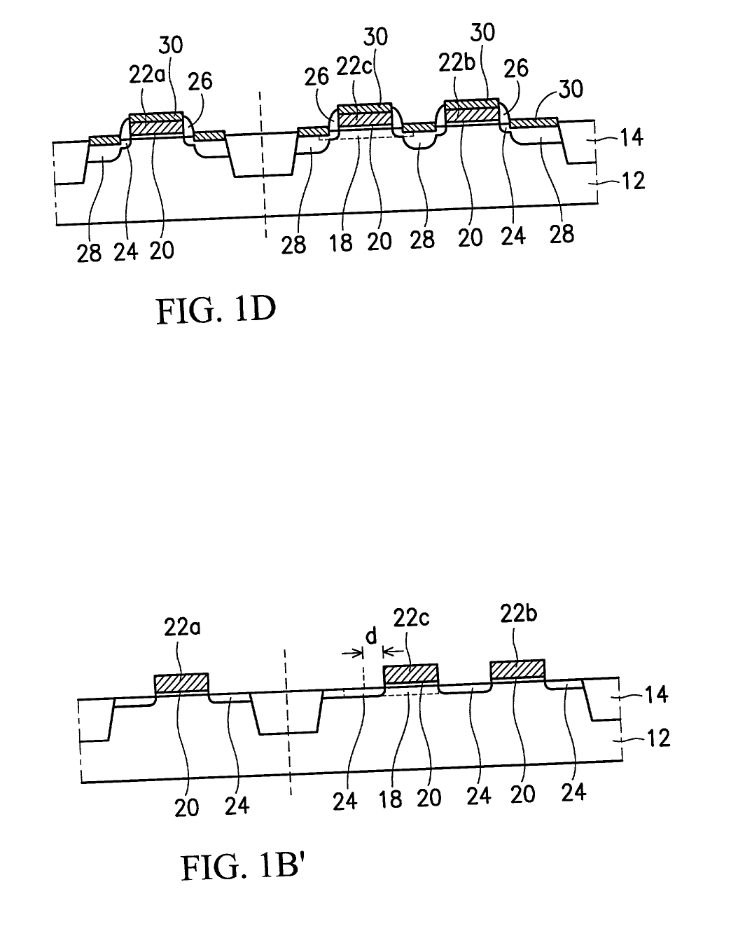

### DETAILED DESCRIPTION OF THE PREFERRED EMBODIMENT

[First Embodiment]

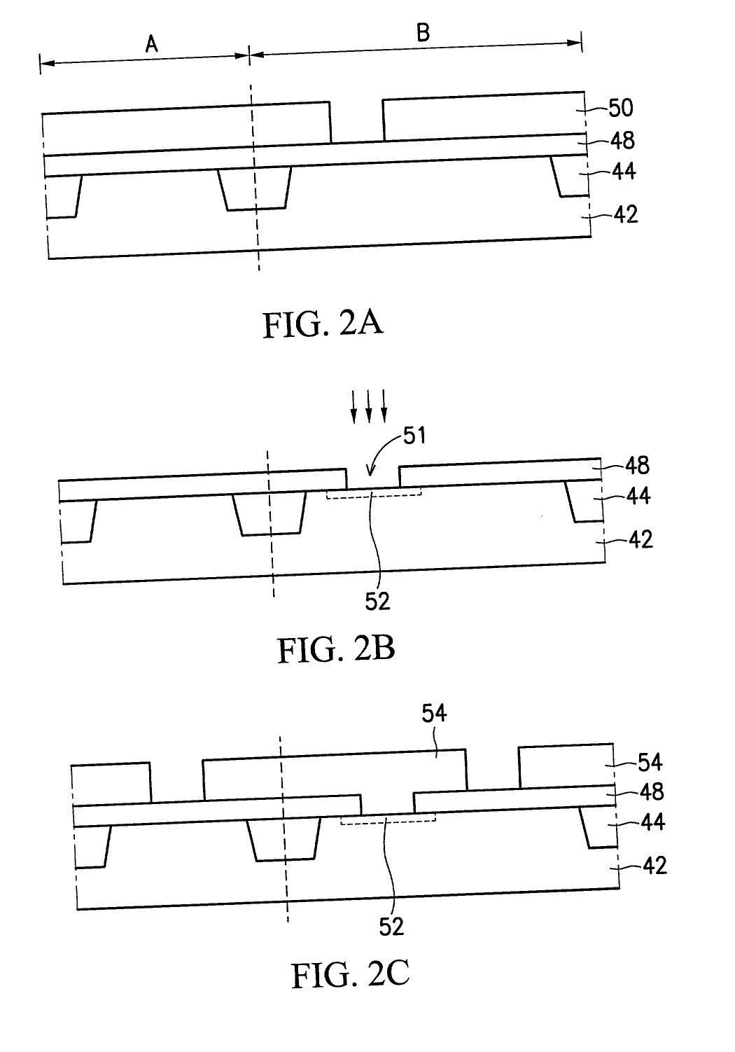

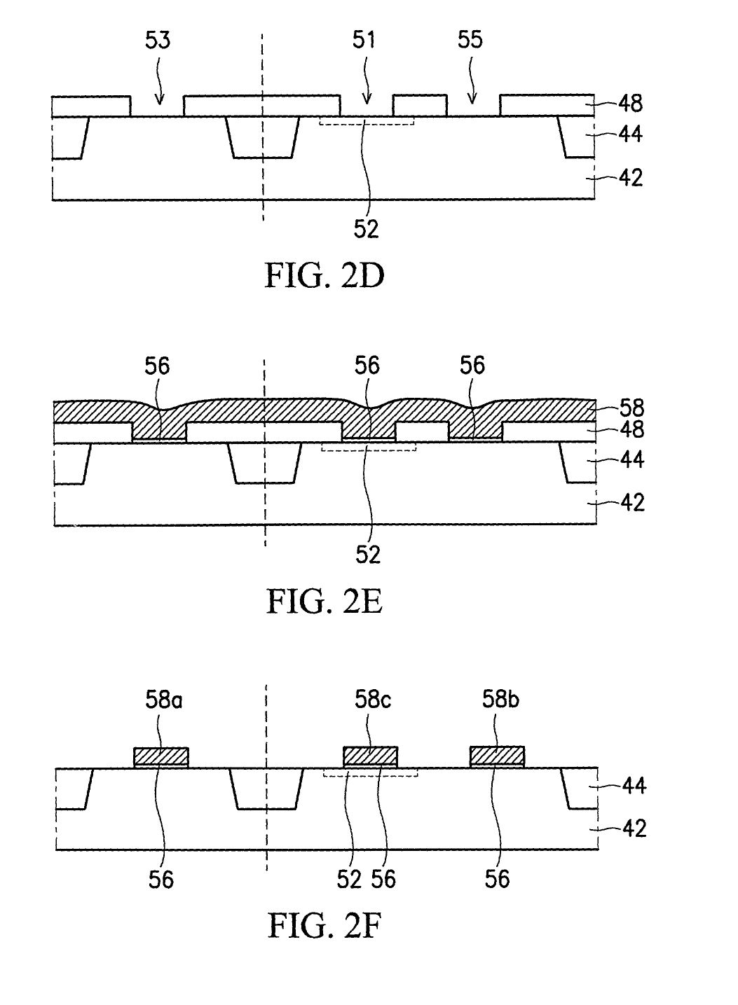

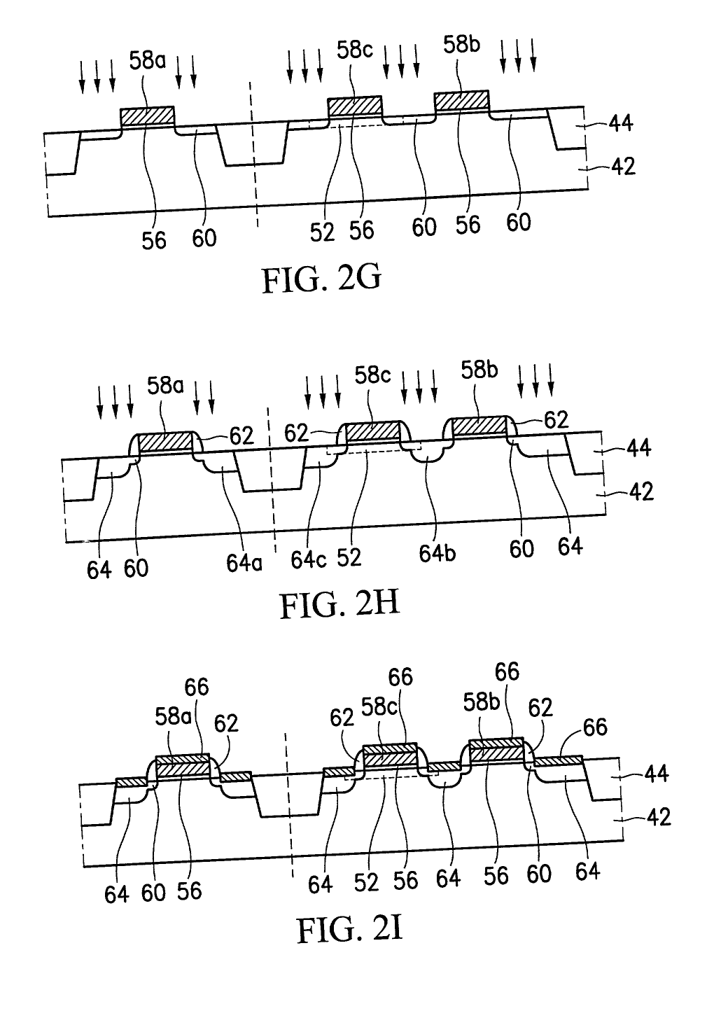

Please refer to FIGS. 2A to 2I, which show a method of forming a dummy gate electrode of an ESD protecting device according to the first embodiment of the present invention. As shown in FIG. 2A, a p-type semiconductor substrate 42 has a plurality of isolation regions 44 by a well-known device isolating process such as a local oxidation of silicon (LOCOS) process or a shallow trench process to separate active areas, where an internal circuit device region A and an ESD protecting device region B are defined. First, a sacrificial layer 48 and a first photoresist layer 50 are sequentially formed on the substrate 42. The sacrificial layer 48 is formed by depositing a pad oxide layer and a silicon nitride layer on the substrate 42. The photoresist layer 50 is patterned to expose a first predetermined area of the sacrificial layer 48 on region B. As shown in FIG. 2B, by using the first photoresist layer 50 as a mask, a first trench 51 is formed in the sacrificial layer 48 to expose the substrate 42, and then the first photoresist layer 50 is stripped off. Next, using the sacrificial layer 48 as a mask, n-type impurity ions are implanted into the exposed substrate 12 to form a first impurity layer 52.

As shown in FIG. 2C, a second photoresist layer 54 is covered on the sacrificial layer 48 to fill the first trench 51 and then patterned to expose a second predetermined area of the sacrificial layer 48 on region A and a third predetermined area of the sacrificial layer 48 on region B. Next, as shown in FIG. 2D, using the second photoresist layer 54 as a mask, a second trench 53 and a third trench 55 are formed on the sacrificial layer 48 and then the second photoresist layer 54 is removed. The second trench 53 on region A exposes the substrate 42 to define a gate electrode of the internal circuit device. The third trench 55 on region B exposes the substrate 42 to define a gate electrode of the ESD protecting device.

As shown in FIG. 2E, a gate insulating layer 56 is formed on the bottom of the first trench 51, the second trench 53, and the third trench 53, and a polysilicon layer 58 is then deposited on the substrate 42 to fill the first trench 51, the second trench 53, and the third trench 53. Next, by using a mask, the polysilicon layer 58 and the sacrificial layer 48 outside the trenches 51, 53, 55 are removed. As a result, as shown in FIG. 2F, the polysilicon layer 58 remaining in the second trench 53 on region A serves as a gate electrode 58a of the internal circuit device, the polysilicon layer 58 remaining in the third trench 55 on region B serves as a gate electrode 58b of the ESD protecting device, and the polysilicon layer 58 remaining in the first trench 51 over the first impurity layer 52 on region B serves as a dummy gate electrode 58c of the internal circuit device.

The dummy gate electrode 58c which serves as a silicide blocking portion is formed simultaneously with the forming of the gate electrodes 58a, 58b, therefore the process thereof becomes simpler compared with that of the conventional art. Also, the dummy gate electrode 58c is formed before fabricating the transistor, thereby preventing change of characteristics of the transistor.

As shown in FIG. 2G, by using the gate electrodes 58a, 58b and the dummy gate electrode 58c as masks, a second impurity layer 60 is formed by implanting n-type impurity ions into the exposed substrate 42. The second impurity layer 60 is generally called a lightly doped drain (LDD).

As shown in FIG. 2H, by depositing silicon nitride and performing the anisotropic etching process, sidewall spacers 62 are formed at side surfaces of the gate electrodes 58a, 58b and the dummy gate electrode 58c, respectively. Then, a third impurity layer 64 is formed by implanting n-type impurity ions into the exposed substrate 42 by using the sidewall spacers 62, the gate electrodes 58a, 58b and the dummy gate electrode 58c as masks. The third impurity layer 64, which has shallower depth and lower density than the second impurity layer 60, serves as source/drain electrodes of the gate electrode 58a of the internal circuit device and gate electrode 58b of the ESD protecting device together with the first impurity layer 52 and the second impurity layer 60. Besides, the third impurity layer 64b serves as a drain electrode of the dummy gate 58c, and the third impurity layer 64c serves as a part of the drain electrode of the ESD protecting device to form a source/drain-wire contact portion that is connected to various devices in the substrate 42.

As shown in FIG. 2I, a metal layer, such as Ti, Co, Pt, Ni, Pd, Cr, Mo, Ta, W, is formed on the resultant surface of the substrate 42 and then a heat treatment is performed at a temperature of 650-730° C. to have a silicified reaction between the silicon and the metal layer, thereby forming a silicide layer 66, and then a portion of the metal layer where the silicified reaction does not occur is selectively removed. As a result, the silicide layers 66 are formed on the gate electrode 58a of the internal circuit device, the gate electrode 58b of the ESD protecting device, the dummy gate electrode 58c and third impurity layer 64, respectively.

It is noted that the dummy gate electrode 58c, which does not receives a voltage when operating the semiconductor device, is simply utilized to prevent the silicide layer 66 from being formed on impurity layers, that is the drain of the ESD protecting device. Further, the silicide layer 66 is formed on the gate electrode 58b of the ESD protecting device, thereby improving the signal transmitting characteristics of the gate electrode 58b. Finally, since the silicide layer 66 is formed on the source/drain-wire contact portion of the ESD protecting device, the contact resistance is decreased, which results in an improvement in the performance of the semiconductor device.

Compared with the prior art, in the method of forming the dummy gate electrode 58c of the present invention, the first impurity layer 52 is defined by patterning the sacrificial layer 48, and the dummy gate electrode 58c is also defined by patterning the sacrificial layer 58 in the follow-up process. Consequently, this can ensure that the dummy gate electrode 58c is disposed in the middle region of the first impurity layer 52. Without the shift distance between the dummy gate electrode 58c and the first impurity layer 52, the performance of the dummy gate electrode 58c and the semiconductor device are both increased.

[Second Embodiment]

For further increasing the alignment of the gate electrodes 58a, 58b, in the second embodiment of the present invention, a novel design of the first photoresist layer 50 and the second photoresist layer 54 are provided.

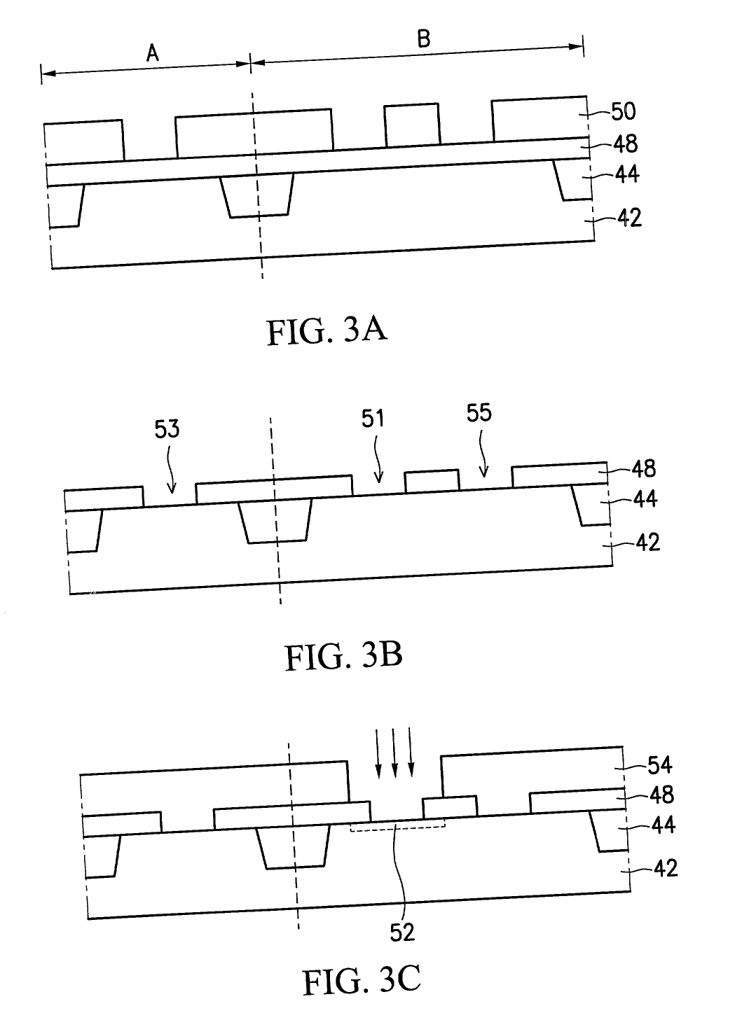

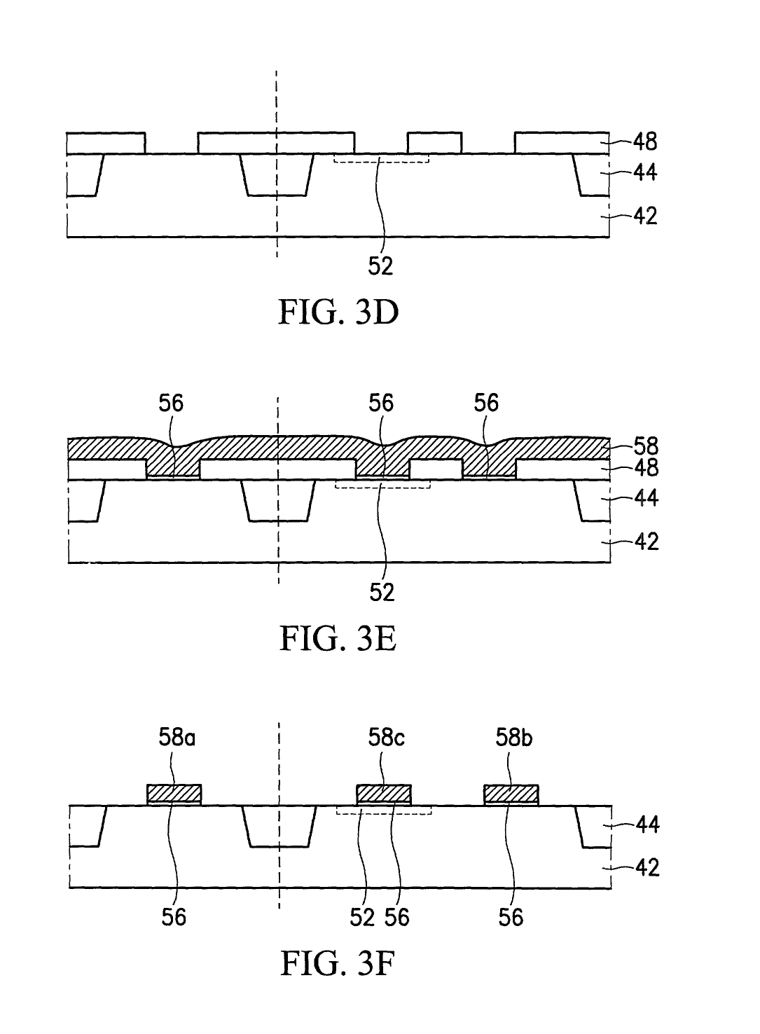

Please refer to FIGS. 3A to 3F, which show a method of fabricating the dummy gate electrode of the ESD protecting device according to the second embodiment of the present invention. As shown in FIGS. 3A and 3B, by using the first photoresist layer 50 which has three openings as the mask, the first trench 51, the second trench 53, and the third trench 55 are simultaneously formed on the sacrificial layer 48. Then, as shown in FIG. 3C, the second photoresist layer 54 patterned on the sacrificial layer 48 fills the second trench 53 and the third trench 55 and exposes the substrate 42 in the first trench 51. Next, by using the sacrificial layer 48 and the second photoresist layer 54 as the masks, the first impurity layer 52 is formed by implanting n-type impurity ions into the exposed substrate 42. After removing the second photoresist layer 54, as shown in FIG. 3D, the three exposed portions of the substrate 42 are defined as the predetermined areas of the gate electrodes 58a, 58b, and the dummy gate electrode 58c.

As shown in FIGS. 3E and 3F, the polysilicon layer 58 deposited on the substrate 42 is patterned to be the gate electrodes 58a, 58b, and the dummy gate electrode 58c according to the above-described method in the first embodiment of the present invention.

The dummy gate electrode 58c on the drain region of the ESD protecting device is only described, it is also possible to form the dummy gate electrode 58c on the source region of the ESD protecting device. Also, in the semiconductor device according to the first and second embodiments of the present invention, the n-type impurity ions are implanted into the p-type semiconductor substrate 42 to fabricate the internal circuit device and the ESD protecting device. However, it is possible that p-type impurity ions are implanted into an n-type semiconductor substrate. In addition, it is also to form p-type wells by implanting the p-type impurity ions into the n-type semiconductor substrate and to fabricate an internal circuit device and an ESD protecting device in the p-type wells.

Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A method of fabricating a semiconductor device, comprising the steps of:
(a) providing a semiconductor substrate of a first conductivity type having an internal circuit device region and an ESD protecting device region;
(b) forming a sacrificial layer having a first trench for exposing a first predetermined area of the substrate on the ESD protecting device region;
(c) forming a first impurity layer of a second conductivity type in the first predetermined area of the substrate on the ESD protecting region;
(d) using a photoresist layer to pattern the sacrificial layer to form a second trench for exposing a second predetermined area of the substrate on the internal circuit device region and a third trench for exposing a third predetermined area of the substrate on the ESD protecting device region;
(e) forming a gate insulating layer on the exposed substrate, and then filling the first trench, the second trench and the third trench with a conductive layer which serves as a dummy gate electrode of the ESD protecting device, a gate electrode of the internal circuit device and a gate electrode of the ESD protecting device respectively;
(f) removing the sacrificial layer and then forming a second impurity layer of the second conductivity type in the exposed substrate at both sides of the gate electrodes and the dummy electrode respectively; and
(g) forming a silicide layer on the gate electrodes, the dummy gate electrode and the second impurity layer.

2. The method as claimed in claim 1, wherein the first impurity layer and the second impurity layer are formed by an ion implantation process.

3. The method as claimed in claim 1, wherein the first impurity layer and the second impurity layer are formed by a high-temperature diffusion process.

4. The method as claimed in claim 1, wherein the first impurity layer is a drain of the ESD protecting device.

5. The method as claimed in claim 1, wherein the first conductivity type is p type.

6. The method as claimed in claim 5, wherein the second conductivity type is n type.

7. The method as claimed in claim 1, wherein the first conductivity type is n type.

8. The method as claimed in claim 7, wherein the second conductivity type is p type.

9. The method as claimed in claim 1, wherein the second impurity layer serves as a source/drain.

10. The method as claimed in claim 1, wherein the method of forming the gate electrodes and the dummy gate comprises the steps of:
forming a polysilicon layer on the sacrificial layer and the gate insulating layer;
performing a chemical mechanical polish (CMP) process on the polysilicon layer;
patterning the polysilicon layer to form the gate electrodes and the dummy gate electrode; and
removing the sacrificial layer.

11. The method as claimed in claim 1, wherein the silicide layer comprises at least one of Ti, Co, Pt, Ni, Pd, Cr, Mo, Ta and W°.

12. A method of fabricating a semiconductor device, comprising the steps of:
(a) providing a semiconductor substrate of a first conductivity type having an internal circuit device region and an ESD protecting device region;
(b) forming a sacrificial layer having a first trench for exposing a first predetermined area of the substrate on the ESD protecting device region, a second trench for exposing a second predetermined area of the substrate on the internal circuit device region, and a third trench for exposing a third predetermined area of the substrate on the ESD protecting device region;
(c) forming a photoresist layer on the sacrificial layer to expose the first predetermined area of the substrate in the first trench is exposed;
(d) forming a first impurity layer of a second conductivity type in the first predetermined area of exposed substrate on the ESD protecting region;
(e) removing the photoresist layer, forming a gate insulating layer on the exposed substrate, and then filling the first trench, the second trench and the third trench with a conductive layer which serves as a dummy gate electrode of the ESD protecting device, a gate electrode of the internal circuit device and a gate electrode of the ESD protecting device respectively;
(f) removing the sacrificial layer and forming a second impurity layer of the second conductivity type in the expoded substrate at both sides of the gate electrodes and the dummy electrode respectively; and
(g) forming a silicide layer on the gate electrodes, the dummy gate electrode and the second impurity layer.

13. The method as claimed in claim 12, wherein the first impurity layer and the second impurity layer are formed by an ion implantation process.

14. The method as claimed in claim 12, wherein the first impurity layer and the second impurity layer are formed by a high-temperature diffusion process.

15. The method as claimed in claim 12, wherein the first impurity layer is a drain of the ESD protecting device.

16. The method as claimed in claim 12, wherein the first conductivity type is p type.

17. The method as claimed in claim 16, wherein the second conductivity type is n type.

18. The method as claimed in claim 12, wherein the first conductivity type is n type.

19. The method as claimed in claim 18, wherein the second conductivity type is p type.

20. The method as claimed in claim 12, wherein the second impurity layer serves as a source/drain.

21. The method as claimed in claim 12, wherein the method of forming the gate electrodes and the dummy gate comprises the steps of:
forming and a polysilicon layer on the sacrificial layer and the gate insulating layer;
performing a chemical mechanical polish (CMP) process on the polysilicon layer;
patterning the polysilicon layer to form the gate electrodes and the dummy gate electrode; and
removing the sacrificial layer.

22. The method as claimed in claim 12, wherein the silicide layer comprises at least one of Ti, Co, Pt, Ni, Pd, Cr, Mo, Ta and W°.
